(19) United States
(12) Patent Application Publication
(10) Pub. No.: US 2005/0104649 A1
(43) Pub. Date: May 19, 2005

(54) Semiconductor device

(76) Inventor: Takemi Yonezawa, Nagano-ken (JP)

Correspondence Address: HARNESS, DICKEY & PIERCE, P.L.C., P.O. BOX 828, BLOOMFIELD HILLS, MI, 48303, US

(21) Appl. No.: 10/937,896

(22) Filed: Sep. 9, 2004

(30) Foreign Application Priority Data
Sep. 10, 2003 (JP) 2003-318434

(51) Int. Cl. H03K 17/16

(52) U.S. Cl. 327/379

(57) ABSTRACT

A differential signal output circuit is provided in a semiconductor chip, wherein resistances are inserted between a pair of output terminals of a pair of signal lines and pads to be connected to the respective output terminals. The resistances are provided inside the semiconductor chip. In particular, the resistance components are inserted between the inductance components of bonding wires and lead frames and capacitance components such as wiring capacitances.

### RELATED APPLICATIONS

This application claims priority to Japanese Patent Application No. 2003-318434 filed Sep. 10, 2003 which is hereby expressly incorporated by reference herein in its entirety.

### TECHNICAL FIELD

The present invention relates to semiconductor devices, and more particularly, to semiconductor devices that reduce EMI noises in the transmission of differential signals.

### BACKGROUND

In recent years, low amplitude differential signal transmission, such as Low Voltage Differential Signaling (or Signal) (LVDS), Reduced Swing Differential Signaling (or Signal) (RSDS), and Mini-LVDS, are attracting attention as technology that supports high-speed data transmission.

LVDS is a standard for data transmission, for example, between a graphics controller of a personal computer and its liquid crystal display panel. Also, RSDS is a standard in which data is sent with low amplitude differential signals to an LVDS receiver circuit, adjusted for the display timing of a liquid crystal display panel by an adjusting circuit, then, outputted again with low amplitude differential signals, and transmitted to a receiver circuit called a source driver in the liquid crystal display panel.

These transmission methods are used for transmission of data signals for pictures or the like and clock signals, which are transmitted with low amplitude differential signals, and therefore are characterized in that ElectroMagnetic Interference (EMI) noises are difficult to generate, and they are resistive to external noises.

In a semiconductor device including a semiconductor chip such as a silicon chip with an integrated circuit formed therein, there are cases where input/output cells (I/O cells) interfacing with an external circuit are disposed in an outer peripheral section of the chip. In this case, pads may be disposed as electrodes for electrical connection with the external circuit in an area further outside of these I/O cells. Each of the pads is electrically connected to each of the corresponding I/O cells. The I/O cells are provided for connecting the integrated circuit formed within the semiconductor chip to the external circuit, and may include an electrostatic protection circuit to protect the inner chip from external static electricity.

For example, in an output circuit of differential signals such as RSDS, electrostatic protection elements and wiring capacitances are attached to the output signal lines of the output circuit, and in addition, inductances of the lead frames, bonding wires and the like are equivalently inserted in series. As such, problems arise in that the output signal waveform of the RSDS output circuit develops a ringing waveform at the rising and falling edges (the rises and falls), and its waveform quality is deteriorated, and EMI noises occur substantially due to high frequency components of the signal.

Therefore, the present invention has been made in view of the problems described above, and an object is to provide semiconductor devices that can prevent output signal waveforms from generating ringing, and deterioration of waveform quality and generation of EMI noises in differential signal output circuits.

### SUMMARY

A semiconductor device in accordance with the present invention equipped with: an output circuit that is provided in a semiconductor chip and has a pair of output terminals from which differential signals are outputted; and a pair of signal lines provided between the pair of output terminals and a pair of pads to be connected to an external circuit of the semiconductor chip. The pair of signal lines has an inductance component and a capacitance component due to the wirings, and conducts the differential signals to the pair of pads. A resistance is provided in series in each of the pair of signal lines.

According to the structure of the present invention described above, because of the presence of the inductance of the lead frames and bonding wires used for connection with an external circuit and the capacitance of the wirings within the chip (in addition, when there is an electrostatic protection element, its capacitance), etc. in a chip section inside the pads that are electrodes provided in the outer peripheral section of the semiconductor chip, and due to the presence of the impedance thereof, ringing is caused at the rising and falling edges of the output signal waveform. However, because the resistances are inserted between the pads and the differential signal output terminals of the output circuit, which means that the resistances are inserted between the inductance and the capacitance described above, the structure is very effective in suppressing the ringing. As a result, deterioration of the waveform quality and generation of EMI noises can be prevented. Moreover, because the resistances are provided inside the chip according to the present structure, the present structure is advantageous in lowering manufacturing costs, compared to a structure in which resistances are provided outside a chip. This is because the resistances are provided within the chip, and the resistances can be formed at the same time when transistors are formed in an ordinary semiconductor manufacturing process, and a special manufacturing process does not need to be conducted. In contrast, in the case of the structure in which resistances are provided outside a chip, a print pattern defining resistances must be formed for each wiring pattern, which leads to higher costs.

A semiconductor device in accordance with the present invention comprises: an output circuit that is provided in a semiconductor chip and has a pair of output terminals from which differential signals are outputted; and a pair of signal lines provided between the pair of output terminals and a pair of pads to be connected to an external circuit of the semiconductor chip. The pair of signal lines has an inductance component and a capacitance component due to the wirings, and conducts the differential signals to the pair of pads. A resistance is provided in series in each of a pair of signal lines inside the output circuit leading up to the pair of output terminals.

According to the structure of the present invention described above, because of the presence of the inductance of the lead frames and bonding wires used for connection with an external circuit and the capacitance of the wirings within the chip (in addition, when there is an electrostatic protection element, its capacitance), etc. in a chip section inside the pads that are electrodes provided in the outer peripheral section of the semiconductor chip, and due to the presence of the impedance thereof, ringing is caused at the rising and falling edges of the output signal waveform. However, because the resistances are inserted in the output signal lines in series within the output circuit leading up to the pair of output terminals, a damping effect is obtained, which is effective in suppressing the ringing. As a result, deterioration of the waveform quality and generation of EMI noises can be alleviated. Moreover, because the resistances are provided inside the chip according to the present structure, the present structure is advantageous in lowering manufacturing costs, compared to a structure in which resistances are provided outside a chip.

A semiconductor device in accordance with the present invention comprises: an output circuit that is provided in a semiconductor chip and has a pair of output terminals from which differential signals are outputted; a pair of signal lines provided between the pair of output terminals and a pair of pads to be connected to an external circuit of the semiconductor chip. The pair of signal lines has an inductance component and a capacitance component due to the wirings, and conducts the differential signals to the pair of pads. An I/O cell provided on the pair of signal lines is equipped with a function to interface with the external circuit to be connected to the pair of pads. A resistance is provided in series in each signal line between the I/O cell and the pair of pads.

According to the structure of the present invention described above, the pads are electrically connected to the corresponding I/O cells, and the I/O cells connect an integrated circuit (inner cells including the output circuit) formed inside the semiconductor chip to the external circuit, and may often include electrostatic protection elements to protect the inner integrated circuit from external static electricity. Accordingly, when I/O cells are provided inside a semiconductor chip, the capacitance component of the electrostatic protection elements may resonate with the inductance of the lead frames, bonding wires and the like that are used for connection with the external circuit, which causes ringing. However, this ringing can be effectively suppressed by the resistance components provided between the I/O cells and the pads.

Furthermore, in accordance with the present invention, the resistance comprises a polysilicon resistance or a diffusion resistance formed by a semiconductor process.

According to the structure described above, a polysilicon resistance or a diffusion resistance can be formed as the resistance by introduction of impurities with an ordinary semiconductor process.

### BRIEF DESCRIPTION OF THE DRAWINGS

FIG. 1 is an equivalent circuit diagram of an RSDS circuit in a semiconductor device in accordance with Exemplary Embodiment 1 of the present invention.

FIGS. 2(A) and (B) are diagrams for describing low amplitude differential signals transmitted in RSDS.

FIG. 3 is a diagram indicating the ringing suppression effect in Exemplary Embodiment of FIG. 1.

FIG. 4 is a view showing an exemplary structure of a semiconductor chip.

FIG. 5 is a view showing another exemplary structure of a semiconductor chip.

FIGS. 6(A) and (B) show circuit diagrams indicating portions of a semiconductor device in accordance with Exemplary Embodiment 2 of the present invention.

FIG. 7 is an equivalent circuit diagram of an RSDS output circuit in a semiconductor device in accordance with Exemplary Embodiment 3 of the present invention.

FIG. 8 is a diagram indicating the ringing suppression effect in Exemplary Embodiment 3 of FIG. 7.

### DETAILED DESCRIPTION

Embodiments of the present invention are now described with reference to the accompanying drawings.

### EXEMPLARY EMBODIMENT 1

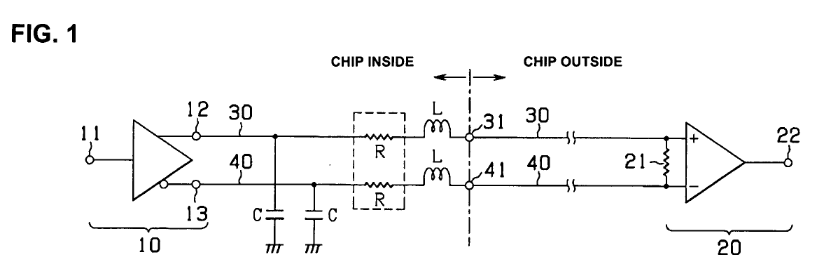

FIG. 1 shows an equivalent circuit diagram of an RSDS circuit in a semiconductor device in accordance with Exemplary Embodiment 1 of the present invention.

In the RSDS circuit shown in FIG. 1, an RSDS output circuit (hereafter, driver) 10 that transmits differential signals and an RSDS receiver circuit (hereafter, receiver) 20 that receives the transmitted differential signals are connected with forward signal line 30 and return signal line 40 having a characteristic impedance of 50 Ω, and the signal lines 30 and 40 are terminated with a resistance 21 of 100 Ω on the input side of the receiver 20. The driver 10 drives an electric current of about 4 mA, and generates a voltage of about 400 mV at the terminating resistance 21. The forward signal line 30 and the return signal line 40 have equal electric characteristics, and form a so-called balanced transmission path, whereby one signal is transmitted by these two transmission paths in the RSDS circuit. The driver 10 generates, based on a single end input signal from an input terminal 11, differential signals in a mutually inverted relation, which causes a potential difference between the forward signal line 30 and the return signal line 40, and outputs the same. On the other hand, the receiver 20 receives the differential signals outputted between the forward signal line 30 and the return signal line 40 with a comparator, converts the same into a single end signal, and outputs the same from an output terminal 22.

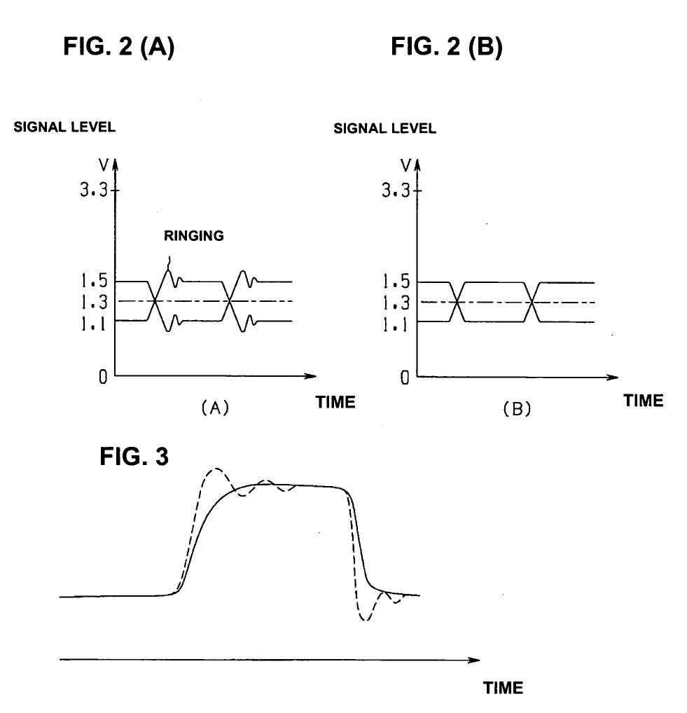

The RSDS circuit carries a signal current Is generated on the driver 10 side to the balanced transmission lines composed of the forward signal line 30 and the return signal line 40, and to the terminating resistance 21 on the receiver 20 side, thereby generating a signal voltage at the terminating resistance 21 to transmit the signal. Signal “1” or “0” (or H level or L level) is transmitted by switching the direction of the flow of the signal current Is on the driver 10 side, and the receiver 20 side detects and recognizes the direction as the magnitude (large or small) of the signal voltage. In the RSDS circuit, a signal is transmitted with the low amplitude differential signals with its common level being 1.3 V, “0” being 1.1 V, and “1” being 1.5V, as shown in FIG. 2. According to this structure, the signal currents Is that flow respectively in the forward signal line 30 and the return signal line 40 have the same size and their directions are opposite such that the magnetic fields generated with the electric currents of the entire balanced transmission lines are mutually canceled. As a result, EMI noises caused by current fluctuations (falling, rising, etc.) on the transmission system become small, and interference among transmission lines between adjacent ports and simultaneous switching interference among LSIs are small, and thus it can be said that it is suitable for high-speed signal transmission.

In the driver 10, reference numeral 11 denotes an input terminal to which a single end signal is inputted, reference numerals 12 and 13 denote output terminals of the driver 10 which connect differential signals converted by the main body of the driver to the forward and return signal lines 30 and 40, respectively. Between the output terminals 12 and 13 and terminals 31 and 41 corresponding to the pads to which an external circuit outside of the chip is connected, the inductance L of the lead frames and bonding wires used for connection with the external circuit, and the wiring capacitance C within the chip (when there is an electrostatic protection element, its capacitance C is also included) exist. Due to the inductance L and the capacitance C, ringing shown in FIG. 2(A) is generated at the rising and falling edges of the differential signal waveforms outputted from the driver 10 to the signal lines 30 and 40. However, because resistances R, R (indicated in a frame of dotted line) are inserted between the pads 31 and 41 and the output terminals 12 and 13 of the driver 10 that output differential signals, which means that the resistances are inserted between the inductance L and the capacitance C described above, output waveforms in which ringing is suppressed as shown in FIG. 2(B) can be obtained. As a result, deterioration of the waveform quality and generation of EMI noises can be prevented.

FIG. 3 indicates the effect of suppressing ringing, in which a waveform indicated by the dotted line is a conventional output waveform of a circuit that lacks the resistances R, R from the equivalent circuit of FIG. 1, and ringing occurs at the rising and falling edges thereof. A waveform indicated by the solid line is an output waveform of the present invention in which ringing is suppressed, provided in the state in which the resistances R, R are inserted as indicated in FIG. 1.

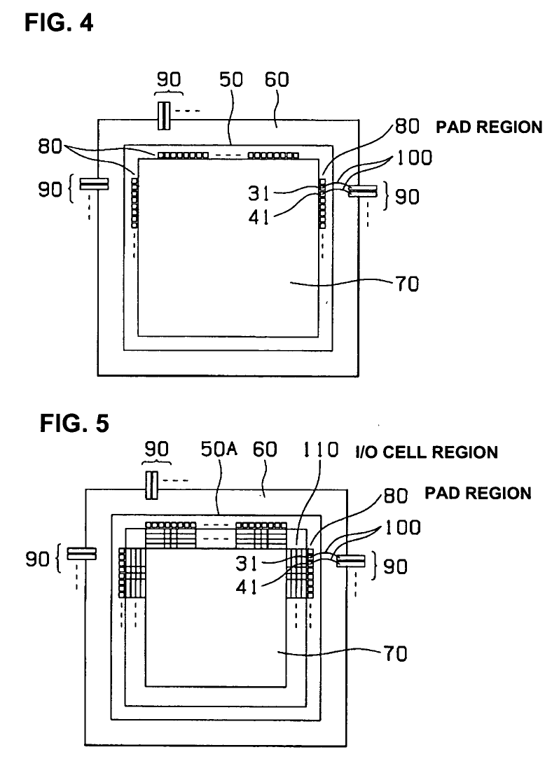

FIG. 4 shows a state in which a semiconductor chip 50 such as a silicon chip on which the drivers described above are mounted is stored in a resin package 60, with an upper surface side of the package being removed. The semiconductor chip 50 includes an inner cell region 70 where an integrated circuit including the drivers is formed, and a pad region 80 formed outside a peripheral section of the inner cell region 70 and having electrodes to be electrically connected to an external circuit. In comparison with FIG. 1, pads corresponding to the terminals 31 and 41 in FIG. 1 are indicated by reference numerals 31 and 41 in FIG. 4. Further, the resin package 60 is provided at its outer peripheral section with a plurality of lead frames 90 of copper or the like for electrical connection with a printed circuit board by soldering or the like. The pads in the pad region 80 are electrically connected to the corresponding lead frames 90 by bonding wires 100 of gold or the like.

FIG. 5 shows another exemplary structure of a semiconductor chip, and shows a state in which a semiconductor chip 50A such as a silicon chip having the drivers described above mounted thereon is stored in a resin package 60, with an upper surface side of the package being removed. The semiconductor chip 50A includes an inner cell region 70 where an integrated circuit including the drivers is formed, and an I/O cell region 110 formed outside a peripheral section of the inner cell region 70 toward an outer peripheral section of the chip and having a function to interface with an external circuit. In this case, a pad region 80 having electrodes to be electrically connected to the external circuit is formed outside a peripheral section of the I/O cell region. Each of the pads is electrically connected to each of the corresponding I/O cells. The I/O cells connect the integrated circuit (inner cells) formed in the semiconductor chip 50A to the external circuit, and include, for example, electrostatic protection circuits to protect the inner chip from external static electricity. Other structures and correspondence are similar to those of FIG. 4.

The semiconductor chip 50 or the I/O cells of the 50A have a structure with input cells that receive signals from outside the chip, and output cells that transfer the signals out of the chip.

The inner cell region 70 of the semiconductor chip 50 or 50A may be composed with a circuit section including, for example, an LVDS receiver circuit, a timing adjusting circuit and an RSDS output circuit. Such a circuit section performs the following operations: an input signal transmitted with low amplitude differential signals to the LVDS receiver circuit is converted by the RSDS output circuit into a single end signal, which is then adjusted by the timing adjusting circuit for the display timing of the liquid crystal display panel, outputted again with low amplitude differential signals by the RSDS output circuit, and transmitted to a receiver circuit called a source driver in a liquid crystal display panel, which is an external circuit.

It is noted that FIG. 4 and FIG. 5 show the package structure in which the pads (31, 41) of the semiconductor chip 50 or 50A are connected to the lead frames 90 by the bonding wires 100 (in this case, the inductance components are generated in the pads due to the lead frames and bonding wires).

However, if the package structure in which the pads (31, 41) of the semiconductor chip 50 or 50A are connected to-the lead frames 90 by the bonding wires 100 is not formed, and another structure in which the pads (31, 41) of the semiconductor chip 50 or 50A are provided with metal bumps that are directly bonded to a printed circuit board is formed, the inductance components are generated in the pads due to the bumps.

### EXEMPLARY EMBODIMENT 2

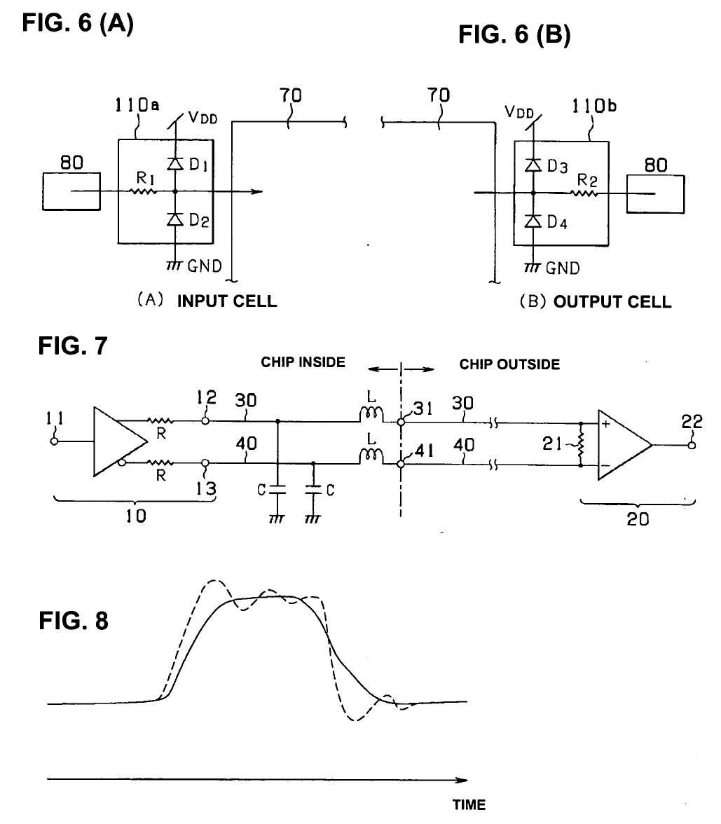

FIG. 6 shows a circuit diagram indicating portions in a semiconductor device in accordance with Exemplary Embodiment 2 of the present invention.

FIG. 6(A) shows a neighboring portion of an input cell having a structure in which a resistance R1 for preventing the generation of ringing is provided on a pad region 80 side within an input cell region 110a that includes an electrostatic protection circuit.

The electrostatic protection circuit in the input cell region 110a may have a structure in which diodes D1 and D2 are connected in series in reverse directions between a power supply voltage VDD and a reference potential point GND (potential VSS). The diodes D1 and D2 have capacitance components. Further, a resistance R1 for ringing suppression is connected between a node of the diodes D1 and D2 and a pad region 80.

A signal inputted through a pad of the pad region 80 passes the input cell region 110a that has the resistance R1 for ringing suppression and is inputted in a circuit section within an inner cell region 70.

FIG. 6(B) shows a neighboring portion of an output cell having a structure in which a resistance R2 for preventing the generation of ringing is provided on a pad region 80 side within an output cell region 110b that includes an electrostatic protection circuit.

The electrostatic protection circuit in the output cell region 110b may also have a structure in which diodes D3 and D4 are connected in series in reverse directions between a power supply voltage VDD and a reference potential point GND (potential VSS). The diodes D3 and D4 also have capacitance components. Further, a resistance R2 for ringing suppression is connected between a node of the diodes D3 and D4 and a pad region 80.

A differential signal outputted from a circuit within the inner cell region 70, for example, a differential signal output circuit, passes the output cell region 110b that has the resistance R2 for ringing suppression and is outputted to a corresponding pad in the pad region 80.

According to Exemplary Embodiment 2 of the present invention, the pads are electrically connected to corresponding I/O cells, and the I/O cells may often include electrostatic protection elements to protect an internal integrated circuit from external static electricity. Accordingly, when the I/O cells are provided inside a semiconductor chip, the capacitance components of the electrostatic protection elements may resonate with the inductance of the lead frames, bonding wires and the like that are used for connection with an external circuit, which causes ringing. However, this ringing can be effectively suppressed by the resistance components provided between the I/O cells and the pads.

### EXEMPLARY EMBODIMENT 3

FIG. 7 shows an equivalent circuit diagram of an RSDS output circuit in a semiconductor device in accordance with Exemplary Embodiment 3.

The semiconductor device shown in FIG. 7 differs from the semiconductor device shown in FIG. 1, and has resistances for ringing suppression R, R inserted in a pair of output signal lines in series within a driver 10A that is an RSDS output circuit. The resistances are disposed in locations different from those in the structure of FIG. 1 where the resistances R, R are provided at locations corresponding to the I/O cell regions. More specifically, the driver 10A is equipped with an input terminal 11 and output terminals 12 and 13 before and after its driver main body, respectively, and the resistances R, R for ringing suppression are provided between the driver main body and the output terminals 12 and 13.

Even with such a structure, the output waveform outputted from the semiconductor chip including the driver 10A becomes a waveform in which ringing is suppressed, as indicated by the solid line in FIG. 8.

FIG. 8 indicates the ringing suppression effect, in which a waveform indicated by the dotted line is a conventional output waveform of a circuit that lacks the resistances R, R from the equivalent circuit of FIG. 1, and ringing occurs. A waveform indicated by the solid line is an output waveform of the present invention in which ringing is suppressed, provided in the state in which the resistances R, R are inserted as indicated in FIG. 7.

It is noted that, in accordance with the present invention, the resistances inserted for ringing suppression can be formed with polysilicon resistances or diffusion resistances that are formed by a semiconductor manufacturing process.

As a result, while polysilicon resistances or diffusion resistances can be formed as the resistances by introduction of impurities in an ordinary semiconductor manufacturing process, the resistances can be formed at the same time when transistors are formed in an ordinary semiconductor manufacturing process, and a special process does not need to be provided.

As described above, in accordance with the embodiments of the present invention, in the differential signal output circuit, there exist the inductance of the lead frames and bonding wires used for connection with an external circuit and the capacitance of the wirings within the chip (in addition, when there are electrostatic protection elements, their capacitance), etc. in a chip section internal to the pads that are electrodes provided in the outer peripheral section of the semiconductor chip, and due to the presence of the impedance thereof, ringing is caused at the rising and falling edges of the output signal waveform. However, because the resistances are inserted between the pads and the differential signal output terminals of the output circuit, or, when I/O cells including electrostatic protection circuits are present, the resistances are inserted between the pads and the I/O cells, which means that the resistances are inserted between the inductance and the capacitance described above, the structure is very effective in suppressing the ringing. As a result, deterioration of the waveform quality and generation of EMI noises can be prevented. Moreover, because the resistances are provided inside the chip according to the present structure, they can be formed concurrently in a semiconductor chip manufacturing process, and the present structure is advantageous in lowering manufacturing costs, compared to a structure in which resistances are provided outside a chip.

In particular, in the case of a structure that includes I/O cells, the I/O cells may often include electrostatic protection elements that connect an integrated circuit formed in a semiconductor chip and an external circuit, and protect the inner chip from external static electricity. Accordingly, the capacitance of the electrostatic protection elements may resonate with the inductance of the lead frames, bonding wires and the like that are used for connection with the external circuit, which causes ringing. However, this ringing can be effectively suppressed by the resistance components.

As described above, according to semiconductor devices of the present invention, in a semiconductor device having a differential signal output circuit and a structure in which outputted differential signals are conducted through a pair of signal lines to a pair of pads, generation of ringing in output signal waveforms is prevented, and deterioration of the waveform quality and generation of EMI noises can be prevented.

The present invention is not limited to the embodiments described above, and each of the embodiments may be appropriately modified and implemented within the scope of the present invention.

1. A semiconductor device comprising:
an output circuit provided in a semiconductor chip, the output circuit having a pair of output terminals from which differential signals are outputted; and
a pair of signal lines provided between the pair of output terminals and a pair of pads to be connected to an external circuit of the semiconductor chip, the pair of signal lines having an inductance component and a capacitance component due to wirings, and conducting the differential signals to the pair of pads,
wherein a resistance is provided in series in each of the pair of signal lines.

2. A semiconductor device comprising:
an output circuit provided in a semiconductor chip, the output circuit having a pair of output terminals from which differential signals are outputted; and
a pair of signal lines provided between the pair of output terminals and a pair of pads to be connected to an external circuit of the semiconductor chip, the pair of signal lines having an inductance component and a capacitance component due to wirings, and conducting the differential signals to the pair of pads,
wherein a resistance is provided in series in each of the pair of signal lines inside the output circuit leading up to the pair of output terminals.

3. A semiconductor device comprising:
an output circuit provided in a semiconductor chip, the output circuit having a pair of output terminals from which differential signals are outputted;
a pair of signal lines provided between the pair of output terminals and a pair of pads to be connected to an external circuit of the semiconductor chip, the pair of signal lines having an inductance component and a capacitance component due to wirings, and conducting the differential signals to the pair of pads; and
an I/O cell provided on the pair of signal lines and interfacing with the external circuit to be connected to the pair of pads,
wherein a resistance is provided in series in each signal line between the I/O cell and the pair of pads.

4. A semiconductor device according to claim 1, wherein the resistance further comprises at least one of a polysilicon resistance and a diffusion resistance.

5. A semiconductor device according to claim 2, wherein the resistance further comprises at least one of a polysilicon resistance and a diffusion resistance.

6. A semiconductor device according to claim 3, wherein the resistance further comprises at least one of a polysilicon resistance and a diffusion resistance.
